(19) United States
(12) Patent Application Publication
(10) Pub. No.: US 2014/0262033 A1
(43) Pub. Date: Sep. 18, 2014

(54) GAS SLEEVE FOR FORELINE PLASMA ABATEMENT SYSTEM

(71) Applicant: APPLIED MATERIALS, INC., Santa Clara, CA (US)

(72) Inventors: ANDREW HERBERT, Lake Oswego, OR (US); COLIN JOHN DICKINSON, San Jose, CA (US)

(73) Assignee: APPLIED MATERIALS, INC., Santa Clara, CA (US)

(21) Appl. No.: 14/184,667

(22) Filed: Feb. 19, 2014

Related U.S. Application Data
(60) Provisional application No. 61/779,815, filed on Mar. 13, 2013.

(51) Int. Cl. H01J 37/32

(52) U.S. Cl. CPC H01J 37/32871
USPC 156/345.29; 422/176

(57) ABSTRACT

Methods and apparatus for protecting an inner wall of a foreline of a substrate processing system are provided herein. In some embodiments, an apparatus for treating an exhaust gas in a foreline of a substrate processing system includes a gas sleeve generator including a gas sleeve generator comprising a body having a central opening disposed through the body; a plenum disposed within the body and surrounding the central opening; an inlet coupled to the plenum; and an annulus coupled at a first end to the plenum and forming an annular outlet at a second end opposite the first end, wherein the annular outlet is concentric with and open to the central opening. The gas sleeve generator may be disposed upstream of a foreline plasma abatement system to provide a sleeve of a gas to a foreline of a substrate processing system.

### CROSS-REFERENCE TO RELATED APPLICATIONS

This application claims benefit of U.S. provisional patent application Ser. No. 61/779,815, filed Mar. 13, 2013, which is herein incorporated by reference in its entirety.

### FIELD

Embodiments of the present invention generally relate to substrate processing equipment, and more specifically, to abatement systems for use with substrate processing equipment.

### BACKGROUND

Some substrate process chamber exhaust treatment systems pre-treat process chamber exhaust in an exhaust foreline of the process chamber prior to delivery to primary abatement systems that remove and/or destroy desired materials in the exhaust stream. Such exhaust treatment systems are referred to herein as foreline abatement systems. Some foreline abatement systems use radio frequency (RF) energy provided to an RF coil disposed about a dielectric tube inserted in line with the foreline to facilitate ignition of exhaust gases flowing through the dielectric tube to form a plasma. However, the inventors have observed that the persistent exhaust gas flow produces undesirable accumulation of solid material (e.g., silicon) within the foreline. The accumulation of these deposits undesirably results in downtime of the process system for maintenance to remove the deposits.

Therefore, the inventors have provided embodiments of an improved foreline abatement system that can provide reduced material deposits during use.

### SUMMARY

Methods and apparatus for protecting an inner wall of a foreline of a substrate processing system are provided herein. In some embodiments, an apparatus for treating an exhaust gas in a foreline of a substrate processing system includes a gas sleeve generator including a gas sleeve generator comprising a body having a central opening disposed through the body; a plenum disposed within the body and surrounding the central opening; an inlet coupled to the plenum; and an annulus coupled at a first end to the plenum and forming an annular outlet at a second end opposite the first end, wherein the annular outlet is concentric with and open to the central opening. The gas sleeve generator may be disposed upstream of a foreline plasma abatement system to provide a sleeve of a gas to a foreline of a substrate processing system.

In some embodiments, a substrate processing system includes a process chamber; a foreline coupled to the process chamber to allow a flow of exhaust from the process chamber; a foreline plasma abatement system coupled to the foreline to abate exhaust flowing through the foreline; a gas source to provide at least one of water vapor or an inert gas; and a gas sleeve generator disposed in the foreline upstream of the foreline plasma abatement system and coupled to the gas source to generate a sleeve of the at least one of water vapor or an inert gas between the exhaust and inner walls of the foreline.

Other and further embodiments of the present invention are described below.

### BRIEF DESCRIPTION OF THE DRAWINGS

Embodiments of the present invention, briefly summarized above and discussed in greater detail below, can be understood by reference to the illustrative embodiments of the invention depicted in the appended drawings. It is to be noted, however, that the appended drawings illustrate only typical embodiments of this invention and are therefore not to be considered limiting of its scope, for the invention may admit to other equally effective embodiments.

FIG. 1 depicts a schematic view of a processing system having a foreline abatement system in accordance with some embodiments of the present invention.

FIG. 2 is an isometric view of a gas sleeve generator of a foreline abatement system in accordance with some embodiments of the present invention.

FIG. 3 is a cutaway view of the gas sleeve generator of FIG. 2 in accordance with some embodiments of the present invention.

To facilitate understanding, identical reference numerals have been used, where possible, to designate identical elements that are common to the figures. The figures are not drawn to scale and may be simplified for clarity. It is contemplated that elements and features of one embodiment may be beneficially incorporated in other embodiments without further recitation.

### DETAILED DESCRIPTION

Embodiments of methods and apparatus for abatement of exhaust in a foreline of a substrate processing system are provided herein. Embodiments of the apparatus may advantageously provide a reduction, deceleration, or elimination of accumulation of material on inner surfaces of the apparatus as compared to conventionally utilized exhaust treatment systems. In some embodiments, the inventive apparatus provided is modular to advantageously be retrofit into existing systems.

FIG. 1 depicts a schematic view of a processing system 100 having a foreline abatement system 101 for treating exhaust gas in a foreline 110 in accordance with some embodiments of the present invention. The processing system 100 includes a foreline plasma abatement system (FPAS) 145 coupled to a foreline 110 (e.g., a conduit) of a process chamber 105. A gas sleeve generator 140 is coupled to the foreline 110 upstream of the FPAS 145 to provide a sheath or sleeve of a gas between the chamber effluent or exhaust flowing in the foreline 110 and the walls of the foreline 110 at least proximate the FPAS 145, as discussed in more detail below. A gas source 115 is coupled to the gas sleeve generator 140 to provide a sleeve gas to the gas sleeve generator 140.

The process chamber 105 may be any process chamber suitable to perform a process on a substrate. In some embodiments, the process chamber 105 may be part of a processing tool, for example a cluster tool, in line processing tool or the like. Non-limiting examples of such tools include substrate processing systems such as those used in semiconductor, display, solar, or light emitting diode (LED) manufacturing processes. Vacuum pressure maintained in the foreline 110 draws exhaust gases resultant from processes performed in the process chamber 105 through the foreline 110. The exhaust gases may be any gases, for example such as residual process gases or byproduct gases that require removal from the process chamber 105. In some embodiments, the exhaust gases include perfluorocarbons (PFC's) and global warming gases (GWG's). In some embodiments, the exhaust gases include materials that may accumulate on surfaces of the foreline 110, such as particulate or gases that may condense on the foreline 110 surfaces. In some embodiments, such materials may include, for example, silicon. For example, silicon tetrafluoride (SiF₄) is generated by etching of silicon with fluorine and is broken apart during plasma abatement. However, dissociation of the SiF₄ gas leaves silicon atoms that can deposit on cold walls of the foreline plasma abatement system.

The foreline 110 may be coupled to a vacuum pump 150 or other suitable pumping apparatus to pump the exhaust gases from the process chamber 105 to appropriate downstream exhaust handling equipment (such as abatement equipment or the like). In some embodiments, the vacuum pump 150 may be a roughing pump or backing pump, such as a dry mechanical pump, or the like. In some embodiments, the vacuum pump 150 may have a variable pumping capacity with can be set at a desired level, for example, to control or provided addition control of pressure in the foreline 110. In some embodiments, the foreline 110 carries process gas at up pressures up to about 1 Torr, such as about 50 mTorr to about 1 Torr, although other pressures may be used as required for a particular application.

The FPAS 145 is disposed in-line with the foreline 110, between the process chamber 105 and the vacuum pump 150, and facilitates treatment or abatement of the exhaust gases from the process chamber 105. For example, the FPAS 145 includes a power source 146, such as an RF power source, coupled to the foreline 110, or to a conduit 147 disposed in-line with the foreline 110, to provide power to facilitate the plasma treatment of the exhaust gases. The power source 146 provides RF energy at a desired frequency and power sufficient to form a plasma within the FPAS 145 such that the exhaust gas flowing through the foreline 110 may be treated with the plasma (e.g., at least partially broken down into one or more of ions, radicals, elements, smaller molecules, or the like). In some illustrative embodiments, the power source 146 may be a variable frequency power source capable of providing RF energy at a range of frequencies. In some illustrative embodiments, the power source 146 may provide about 2 to about 3 kW of RF energy at a frequency of about 1.9 to about 3.2 MHz.

The gas source 115 is coupled to the gas sleeve generator 140 by conduit 130 for introduction of the gas to the foreline 110 as a sleeve. A control valve 136 (or first control valve) may be provided to selectively couple the gas source 115 to the gas sleeve generator 140. The conduit 130 has a diameter selected based on the geometry of the gas sleeve generator 140 to minimize any limitation of flow provided to the gas sleeve generator 140 (e.g., so that a substantially uniform sleeve of gas may be generated about inner peripheral surfaces of the foreline 110). In some embodiments, the conduit 130 has a diameter to match the primary flow path of the foreline 110. For example, if the foreline 110 is about 4 inches in diameter, the conduit 130 may be about 0.5 inches in diameter. Optionally, a test port 135 may be provided proximate the control valve 136, for example, to determine a pressure drop across the control valve in order to calculate the flow rate of the gas provided by the gas source 115 to the gas sleeve generator 140.

In some embodiments, the gas source 115 provides water vapor. In some embodiments, the gas source provides an inert gas, such as nitrogen or a noble gas (e.g., argon and the like). In embodiments where the gas source provides water vapor, the conditions within the system may be controlled to prevent or minimize condensation of the water vapor within the conduits of the system. For example, the gas source 115 produces water vapor at a specific temperature and pressure controlled such that the water vapor does not condense into liquid form within the foreline abatement system 101. In some embodiments, the water vapor may be provided at a temperature near an ambient temperature of the foreline abatement system 101. In some embodiments, the water vapor may be provided at a flow rate of about 0.2 to about 2 slm to the gas sleeve generator 140.

Optionally, in some embodiments, the gas source 115 is additionally coupled to the foreline 110 upstream of the gas sleeve generator 140, for example, by conduit 120. Providing the gas from the gas source 115 upstream of the gas sleeve generator 140 advantageously facilitates mixing of the gas within the exhaust stream, rather than remaining predominantly as a sleeve. Such mixing may enhance destruction of the desired constituents of the exhaust, for example, when the gas is a reagent (such as water vapor or the like). Alternatively, such mixing may advantageously dilute the exhaust, for example, when the gas is inert (such as nitrogen, noble gases, or the like). A control valve 125 (or second control valve) may be provided to selectively couple the gas source 115 to the foreline 110. Optionally, a test port (similar to the test port 135 shown for control valve 136) may be provided proximate the control valve 125, for example, to determine a pressure drop across the control valve in order to calculate the flow rate of the gas provided by the gas source 115 to the foreline 110 upstream of the gas sleeve generator 140.

In embodiments where the gas source provides water vapor to form the gas sleeve, the water vapor advantageously assists in the deconstruction of PFCs. For example, water vapor acts as a reagent for silicon tetrafluoride (SiF₄) or carbon tetrafluoride (CF₄) gases such that there is preferential recombination downstream in the system. In such an example, carbon may combine with oxygen to form carbon dioxide and fluorine may combine with hydrogen to form HF. HF may be readily wet scrubbed to ensure removal of fluorine ions from the exhaust stream.

As discussed above, the gas sleeve generator 140 is coupled to the foreline 110 upstream of the FPAS 145 to provide a sheath of a gas between the chamber effluent or exhaust flowing in the foreline 110 and the walls of the foreline 110 at least proximate the FPAS 145. The gas sleeve generator 140 is disposed sufficiently close to the FPAS 145 to facilitate maintaining the generated sleeve of gas within the conduit (e.g., the foreline 110 or the conduit 147 within the FPAS 145) to provide a barrier to deposition of materials on surfaces within the FPAS 145.

FIG. 2 depicts an isometric view of the gas sleeve generator 140 in accordance with some embodiments of the present invention. The gas sleeve generator 140 generally comprises a body 202 having a central opening 204 corresponding to the diameter of the foreline 110. The body includes an interior volume (described below with respect to FIG. 3) coupled to an inlet 208, to receive a gas from the gas source 115 via conduit 130, and to an annular slot 206 to deliver the gas to the foreline 110 (or FPAS 145) via the central opening 204. In some embodiments, the gas sleeve generator 140 may advantageously be sized to facilitate ease of installation of the gas sleeve generator 140 in line with an existing FPAS 145. For example, in some embodiments, the gas sleeve generator 140 is relatively thin to allow insertion of the gas sleeve generator 140 between the existing connection flanges of the foreline 110 and the FPAS 145 (e.g., with enough play in the conduit, the gas sleeve generator 140 may be installed without cutting the foreline 110 conduit and re-welding connections). In some embodiments the gas sleeve generator 140 is about 33 mm thick.

In some embodiments, the body 202 of the gas sleeve generator 140 comprises a first half 205 and a second half 210. Two piece construction of the body facilitates ease of rebuilding, re-machining of sleeve geometry, and cleaning, if necessary. The first half 205 and the second half 210 may be coupled together in any suitable fashion, such as via a plurality of bolts disposed in holes 215 disposed along the perimeter of the first and second halves, thereby providing a singular assembly for ease of handling, installation, and removal of the gas sleeve generator 140. A plurality of through holes 220 are provided to couple the gas sleeve generator 140 to the FPAS 145 and foreline 110 using the existing flange connectors (e.g., providing longer bolts to accommodate the thickness of the gas sleeve generator 140). In some embodiments, three holes 215 and three through holes 220 are provided, although other numbers of fasteners may be used.

FIG. 3 is a cutaway view 300 taken along line 3-3 of the gas sleeve generator 140 of FIG. 2 for treating a primary exhaust gas flow 350 in the foreline 110 (or conduit 147 of the FPAS 145) in accordance with some embodiments of the present invention. The first half 205 and the second half 210 together enclose a plenum 305. The plenum 305 may be defined by a recess in either or both of the first or second halves 205, 210. In some embodiments, the first half 205 includes a recess that when placed against the second half 210, forms the plenum 305. The inlet 208 fluidly couples the conduit 130 to the plenum 305. In some embodiments, the inlet 208 is provided in the first half 205. The plenum 305 substantially surrounds the central opening 204 and is fluidly coupled to an annulus 325 (e.g., the annular slot 206) formed via a flange 340. The flange 340 extends parallel to the central opening 204 and at least partially overlaps the second half 210 to define the annulus 325 between the flange 340 and a central-opening facing wall of the second half 210. A first end of the annulus 325 is coupled to the plenum 305 and a second end of the annulus coupled to an annular outlet 330. The annulus 325 is substantially smaller than the plenum 305 such that the flow restriction provided facilitates more uniform gas delivery to the central opening 204 through the annular outlet 330. The annulus 325 thus distributes gas around the primary exhaust gas flow 350 via the annular outlet 330.

In locations where a seal is desired, such as at any connection point between the first and second halves 205, 210, or between either of the first or second halves 205, 210 and a connection flange of the foreline 110 or the conduit 147 (e.g., connection flanges 302, 304), a seal may be provided to minimize or prevent any leakage of exhaust out of the foreline 110 or of the gas from the gas source 115. For example, an o-ring 315 is placed in a groove 317 to prevent gas from leaking out of the junction of the first and second halves 205, 210. Similarly, o-rings may be placed in respective grooves in connection flanges 302, 304 to prevent gas or exhaust from leaking out of the respective junctions of the first and second halves 205, 210 with the connection flanges 302, 304. O-ring grooves may alternatively be formed completely in one surface or partially within two opposing surfaces, or in the opposite surface than as shown in FIG. 3.

In some embodiments, the holes 215 may be threaded in one half (such as the first half 205 in the embodiment shown) to receive bolts 335 to facilitate coupling the first and second halves 205, 210 together with sufficient force to form a seal between the mating surfaces of the first and second halves 205, 210 (for example, by compressing the o-ring 315. A plurality of fasteners, such as bolts 320, may be provided to couple the gas sleeve generator 140 to the foreline 110 and the FPAS 145.

In operation, exhaust/effluent from a process chamber (not shown) may be pumped through the foreline 110 and pass through the gas sleeve generator 140 and FPAS 145 for treating the exhaust gas. The gas source 115 may provide a gas to the gas sleeve generator 140 to form a sleeve of the gas disposed between the exhaust/effluent and the inner walls of the foreline 110 and/or conduit 147 within the FPAS 145. RF energy may be provided by the power source 146 to an RF coil (not shown) of the FPAS 145 to inductively form a plasma within the FPAS 145 for treating the exhaust gas. In some embodiments, the gas sleeve generator 140 provides a sleeve of water vapor to provide a barrier between the process gas and the interior wall of the foreline. In some embodiments, the gas sleeve generator 140 provides a sleeve of nitrogen gas or a noble gas. The barrier provided by the gas sleeve generator 140 advantageously reduces or prevents deposition of materials from the exhaust/effluent on the walls of the foreline 110 or conduit 147 of the FPAS 145. The configuration of the apparatus for treating exhaust gas advantageously may provide a longer service life as compared to conventional apparatus not having a deposition barrier.

While the foregoing is directed to embodiments of the present invention, other and further embodiments of the invention may be devised without departing from the basic scope thereof.

1. An apparatus for treating an exhaust gas in a foreline of a substrate processing system, comprising:
a gas sleeve generator comprising a body having a central opening disposed through the body;
a plenum disposed within the body and surrounding the central opening;
an inlet coupled to the plenum; and
an annulus coupled at a first end to the plenum and forming an annular outlet at a second end opposite the first end, wherein the annular outlet is concentric with and open to the central opening.

2. The apparatus of claim 1, wherein the gas sleeve generator is disposed in line in a foreline upstream of a foreline plasma abatement system.

3. The apparatus of claim 1, wherein the body of the gas sleeve generator further comprises a first half and a second half, wherein the plenum is disposed between the first half and the second half.

4. The apparatus of claim 3, wherein the inlet is disposed in the first half.

5. The apparatus of claim 3, wherein the first half further comprises a flange disposed adjacent to the central opening and axially extending from the first half along the central opening and at least partially overlapping the second half, and wherein the annulus is defined between the flange and the second half.

6. The apparatus of claim 3, wherein the body further comprises a first plurality of holes to couple the first and second halves together and a second plurality of through holes disposed completely through the body.

7. The apparatus of claim 1, further comprising a gas source coupled to the inlet of the gas sleeve generator.

8. The apparatus of claim 7, wherein the gas source provides water vapor.

9. The apparatus of claim 7, wherein the gas source provides an inert gas.

10. An apparatus for treating an exhaust gas in a foreline of a substrate processing system, comprising:
a gas sleeve generator comprising a body having a central opening disposed through the body, wherein the body of the gas sleeve generator further comprises a first half and a second half, and wherein the first half further comprises a flange disposed adjacent to the central opening and axially extending from the first half along the central opening and at least partially overlapping the second half;
a plenum disposed within the body and surrounding the central opening, wherein the plenum is disposed between the first half and the second half of the body;
an inlet coupled to the plenum through the first half of the body; and
an annulus coupled at a first end to the plenum and forming an annular outlet at a second end opposite the first end, wherein the annular outlet is concentric with and open to the central opening, and wherein the annulus is defined between the flange of the first half of the body and a central opening-facing wall of the second half of the body.

11. The apparatus of claim 10, wherein the body further comprises a first plurality of holes to couple the first and second halves together and a second plurality of through holes disposed completely through the body.

12. A substrate processing system, comprising:
a process chamber;
a foreline coupled to the process chamber to allow a flow of exhaust from the process chamber;
a foreline plasma abatement system coupled to the foreline to abate exhaust flowing through the foreline;
a gas source; and
a gas sleeve generator disposed in the foreline upstream of the foreline plasma abatement system and coupled to the gas source to generate a sleeve of a gas provided by the gas source between the exhaust and inner walls of the foreline.

13. The substrate processing system of claim 12, wherein the gas source is additionally coupled to the foreline at a location upstream of the gas sleeve generator.

14. The substrate processing system of claim 12, wherein the gas source provides water vapor.

15. The substrate processing system of claim 12, wherein the gas source provides an inert gas.

16. The substrate processing system of claim 12, wherein the gas sleeve generator comprises:
a body having a central opening disposed through the body;
a plenum disposed within the body and surrounding the central opening;
an inlet coupled to the plenum; and
an annulus coupled at a first end to the plenum and forming an annular outlet at a second end opposite the first end, wherein the annular outlet is concentric with and open to the central opening.

17. The substrate processing system of claim 16, wherein the body of the gas sleeve generator further comprises a first half and a second half, wherein the plenum is disposed between the first half and the second half.

18. The substrate processing system of claim 17, wherein the first half of the body further comprises a flange disposed adjacent to the central opening and axially extending from the first half along the central opening and at least partially overlapping the second half of the body, and wherein the annulus is defined between the flange and the second half.

19. The substrate processing system of claim 17, wherein the body further comprises a first plurality of holes to couple the first and second halves together and a second plurality of through holes disposed completely through the body.

20. The substrate processing system of claim 17, wherein the body further comprises a first plurality of holes to couple the first and second halves together and a second plurality of through holes disposed completely through the body, wherein the gas sleeve generator is coupled to the foreline via the second plurality of through holes.
